(19) United States
(12) Patent Application Publication
(10) Pub. No.: US 2016/0079496 A1
(43) Pub. Date: Mar. 17, 2016

(54) LIGHT-EMITTING DIODE PACKAGE STRUCTURE

(71) Applicant: Genesis Photonics Inc., Tainan City (TW)

(72) Inventors: Jing-En Huang, Tainan City (TW); Shao-Ying Ting, Tainan City (TW); Kuan-Yung Liao, Taipei City (TW); Chih-Ling Wu, New Taipei City (TW); Yi-Ru Huang, Tainan City (TW); Yu-Yun Lo, Tainan City (TW)

(21) Appl. No.: 14/943,036

(22) Filed: Nov. 17, 2015

Related U.S. Application Data
(63) Continuation of application No. 14/513,218, filed on Oct. 14, 2014.

(30) Foreign Application Priority Data
Oct. 14, 2013 (TW) 102136989

(51) Int. Cl. H01L 33/58; H01L 33/60; H01L 33/50; H01L 33/52

(52) U.S. Cl. CPC H01L 33/58; H01L 33/52; H01L 33/60; H01L 33/50

(57) ABSTRACT

A light-emitting diode package structure includes a package carrier, a light guiding component and a light emitting unit. The light guiding component is disposed on the package carrier. The light emitting unit is disposed on an upper surface of light guiding component relatively distant from the package carrier. A horizontal projection area of the light guiding component is greater than that of the light emitting unit. The light emitting unit is adapted to emit a light beam, and a portion of the light beam enters the light guiding component and emits from the upper surface of the light guiding component. An included angle existing between the light beam and a normal direction of the upper surface ranges from 0 degree to 75 degrees.

### CROSS-REFERENCE TO RELATED APPLICATION

This application is a continuation application of and claims the priority benefit of U.S. patent application Ser. No. 14/513,218, filed on Oct. 14, 2014, now pending. The prior U.S. patent application Ser. No. 14/513,218 claims the priority benefit of Taiwan application Ser. No. 102136989, filed on Oct. 14, 2013. The entirety of each of the above-mentioned patent applications is hereby incorporated by reference herein and made a part of this specification.

### BACKGROUND OF THE INVENTION

1. Field of the Invention

The invention generally relates to a package structure, and more particularly, to a light-emitting diode (LED) package structure.

2. Description of Related Art

With the advances in optoelectronic technology, the light-emitting diode (LED) technology used to replace the traditional incandescent bulbs and fluorescent lamps and serving as the new generation light source gradually gets mature. The LED has advantage of low power consumption, small size, non-thermal luminescence and environmental protection, so that its application areas are gradually extended.

In the conventional LED package structure, the LED is disposed in the package carrier and covered by a fluorescent encapsulant. Otherwise, a package encapsulant covers the fluorescent encapsulant and the package carrier. Owing to the LED having the specific light emitting angles, the light emitting from the LED may thus enter the fluorescent encapsulant and the package carrier at the specific angles. As a result, the LED package structure has the limited light emitting angles, unable to have a relatively larger light emitting angle.

### SUMMARY OF THE INVENTION

Accordingly, the invention is directed to a light-emitting diode (LED) package structure, which increases the range of the light emitting angles and brightness thereof.

A light-emitting diode package structure includes a package carrier, a light guiding component and a light emitting unit. The light guiding component is disposed on the package carrier. The light emitting unit is disposed on an upper surface of the light guiding component relatively distant from the package carrier. A horizontal projection area of the light guiding component is greater than that of the light emitting unit. The light emitting unit is adapted to emit a light beam, and a portion of the light beam enters the light guiding component and emits from the upper surface of the light guiding component. Otherwise, an included angle exists between the portion of the light beam and a normal direction of the upper surface, which ranges from 0 degree to 75 degrees.

In an embodiment of the invention, the light guiding component is a transparent plate or a transparent encapsulant.

In an embodiment of the invention, the portion of the light beam enters the light guiding unit, reflected by the package carrier, and emits out from the upper surface of the light guiding component.

In an embodiment of the invention, the light guiding unit includes a transparent unit and a reflecting layer. The reflecting layer is disposed between the transparent unit and the package carrier, and the transparent unit has the upper surface.

In an embodiment of the invention, the portion of the light beam enters the transparent unit of the light guiding component, and the portion the light beam is reflected by the reflecting layer and emits out from the upper surface the transparent unit.

In an embodiment of the invention, the transparent unit is a transparent plate or a transparent encapsulant.

In an embodiment of the invention, the light emitting unit includes a substrate, a first type semiconductor layer, a light emitting layer, and a second type semiconductor layer. The first type semiconductor layer, the light emitting layer, and the second type semiconductor layer are sequentially disposed on the substrate.

In an embodiment of the invention, the thickness of the light guiding component is 0.1 to 2 times of the thickness of the substrate of the light emitting unit.

In an embodiment of the invention, the profiles of the light guiding component and the substrate of the light emitting unit are alike.

In an embodiment of the invention, the refractive index of the light guiding component is smaller than or equal to the refractive index of the substrate of the light emitting unit.

In an embodiment of the invention, the light-emitting diode package structure further includes a transparent cover disposed on the package carrier, and the transparent cover covers the light guiding component and the light emitting unit.

In an embodiment of the invention, an air gap exists between the transparent cover and the package carrier.

In an embodiment of the invention, the material of the transparent cover includes a transparent encapsulant, a glass and a transparent encapsulant doped with the fluorescent material.

In an embodiment of the invention, the light-emitting diode package structure further includes a wavelength-conversion layer disposed on the package carrier, and the wavelength-conversion layer covers the light emitting unit and the light guiding component.

In an embodiment of the invention, the light-emitting diode package structure further includes a package encapsulant disposed on the package carrier, which covers the wavelength-conversion layer, wherein the horizontal projection area of the light guiding component is smaller than a horizontal projection area of the package encapsulant.

In an embodiment of the invention, the upper surface of the light guiding component is a rough surface, and a central line average roughness of the rough surface is between 100 nanometers and 3000 nanometers.

In an embodiment of the invention, the rough surface is a surface with periodic patterns.

In an embodiment of the invention, the package carrier has a recess, and the light emitting unit and the light guiding component are located in the recess.

In an embodiment of the invention, the horizontal projection area of the light guiding component is 1.1 to 5 times of the horizontal projection area of the light emitting unit.

Based on the depiction above, the LED package structure has a light guiding component, wherein the horizontal projection area of the light guiding component is greater than that of the light emitting unit. Therefore, a portion of the light beam emitted by the light emitting unit can expand the range of the light emitting angle of the light emitting unit through the light guiding effect of the light guiding component. As a result, the LED package structure of the invention may have a broader light emitting angle and the brightness thereof can be enhanced.

In order to make the features and advantages of the present invention more comprehensible, the present invention is further described in detail in the following with reference to the embodiments and the accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the invention.

FIG. 1 is a cross-sectional schematic diagram of an LED package structure according to an embodiment of the invention.

FIG. 2 is a cross-sectional schematic diagram of an LED package structure according to another embodiment of the invention.

FIG. 3 is a cross-sectional schematic diagram of an LED package structure according to yet another embodiment of the invention.

FIG. 4 is a cross-sectional schematic diagram of an LED package structure according to yet another embodiment of the invention.

FIG. 5 is a cross-sectional schematic diagram of an LED package structure according to yet another embodiment of the invention.

FIG. 6 is a cross-sectional schematic diagram of an LED package structure according to yet another embodiment of the invention.

### DESCRIPTION OF THE EMBODIMENTS

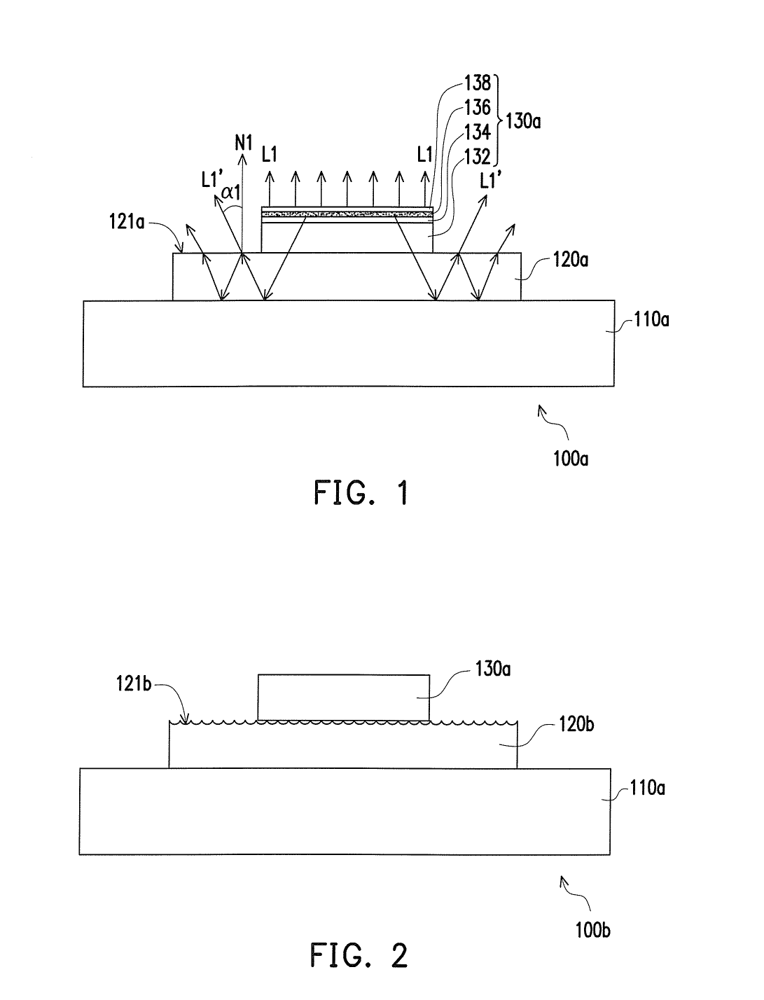

FIG. 1 is a cross-sectional schematic diagram of an LED package structure according to an embodiment of the invention. Referring to FIG. 1, in the present embodiment, the LED package structure 100a includes a package carrier 110a, a light guiding component 120a, and a light emitting unit 130a. The light guiding component 120a is disposed on the package carrier 110a. The light emitting unit 130a is disposed on an upper surface 121a, relatively distant from the package carrier 110a, of the light guiding component 120a. A horizontal projection area of the light guiding component 120a is greater than that of the light emitting unit 130a. The light emitting unit 130a is adapted to emit a light beam L1, and a portion of the light beam L1′ enters the light guiding component 120a, and emits out from the upper surface 121a of the light guiding component 120a. An including angle al existing between the light beam L1′ and a normal direction N1 of the upper surface 121a ranges from 0 degree to 75 degrees.

In more detail, in the present embodiment, the package carrier 110a is, for example, a leadframe or a circuit board with reflective characteristics. The light emitting component 120a is a transparent plate or a transparent encapsulant. The transparent plate is, for example but not limited to, a sapphire substrate, and the transparent encapsulant is, for example not limited to, silicone. The light emitting unit 130a includes a substrate 132, a first type semiconductor layer 134, a light emitting layer 136, and a second type semiconductor layer 138, wherein the first type semiconductor layer 134, the light emitting layer 136, and the second type semiconductor layer 138 are sequentially disposed on the substrate 132. Here, the light emitting unit 130a is, for instance, a horizontal type LED, but the invention is not limited herein. Particularly, the portion of the light beam L1′ emitted by the light emitting unit 130a enters the light guiding component 120a. Moreover, the portion of the light beam L1′ is reflected by the package carrier 110a and emits from the upper surface 121a of the light guiding component 120a. Preferably, the horizontal projection area of the light guiding component 120a is 1.1 to 5 times of the horizontal projection area of the light emitting unit 130a. It should be noted that if the ratio of the horizontal projection areas is smaller than 1.1 times, the light guiding component 120a will not have good light guiding effects, and the light emitting angle of the light emitting unit 130a cannot be effectively expanded. Otherwise, if the ratio of the horizontal projection areas is greater than 5 times, the light guiding component 120a will not be easily fixed on the package carrier 110a.

Referring again to FIG. 1 in the present embodiment, the profiles of the light guiding component 120a and the substrate 132 of the light emitting unit 130a are alike, so as to equivalently enlarge the light emitting angles in every aspect of the light emitting unit 130a and prevent the issues of the non-uniform light emitting. Moreover, the thickness of the light guiding component 120a of the present embodiment is 0.1 to 2 times of the thickness of the substrate 132 of the light emitting unit 130a. If the ratio of thickness is smaller than 0.1 times, the light guiding component 120a will not have good light guiding effects, unable to expand the light emitting angles of the light emitting unit 130a. On the other hand, if the ratio of the thickness is greater than 2 times, the heat may be accumulated inside of the light guiding component 120a, such that the life span of the LED package structure 100a may be curtailed due to the rising temperature. In addition, the refractive index of the light guiding component 120a is smaller than or equal to the refractive index of the substrate 132 of the light emitting unit 130a.

The LED package structure 100a of the present embodiment has the light guiding component 120a, wherein the horizontal projection area of the light guiding component 120a is greater than that of the light emitting unit 130a. That is, the light emitting unit 130a disposed on the light guiding component 120a does not completely cover the upper surface 121a of the light guiding component 120a, and otherwise exposes a portion of the upper surface 121a of the light guiding component 120a. Therefore, the portion of the light beam L emitted by the light emitting unit 130a may emit from the upper surface 121a not covered by the light emitting unit 130a through the light guiding effect of the light guiding component 120a. An included angle al existing between the light beam L1′ and the normal line N1 of the upper surface 121a ranges from 0 degree to 75 degrees, thereby the range of the light emitting angle of the light emitting unit 130a can be effectively expanded. As a result, the LED package structure 100a of the present embodiment may have a broader light emitting angle and the brightness thereof can be enhanced.

It should be noted that reference numbers of the components and a part of contents of the aforementioned embodiment are also used in the following embodiment, wherein the same reference numbers denote the same or like components, and descriptions of the same technical contents are omitted. The aforementioned embodiment can be referred for descriptions of the omitted parts, so that detailed descriptions thereof are not repeated in the following embodiment.

FIG. 2 is a cross-sectional schematic diagram of an LED package structure according to another embodiment of the invention. Referring to FIG. 2, the LED package structure 100b of the present embodiment is similar to the LED package structure 100a of FIG. 1. But, the main difference between them is that the upper surface 121b of the light guiding component 120b of the present embodiment is a rough surface, wherein the central line average roughness of this rough surface is between 100 nanometers and 3000 nanometers, preferably, the rough surface 121b is a surface with periodic patterns.

The upper surface 121b of the light guiding component 120b of the present embodiment is a rough surface. Therefore, the light guiding component 120b have not only the light guiding effect but also the light scattering effect which may scatter out the light beam of the light emitting unit 130a that enters the light guiding component 120b. Thus, the range of the light emitting angle of the light emitting unit 130a can be expanded. As a result, the LED package structure 100b of the present embodiment can have a broader light emitting angle and the brightness thereof can be further enhanced.

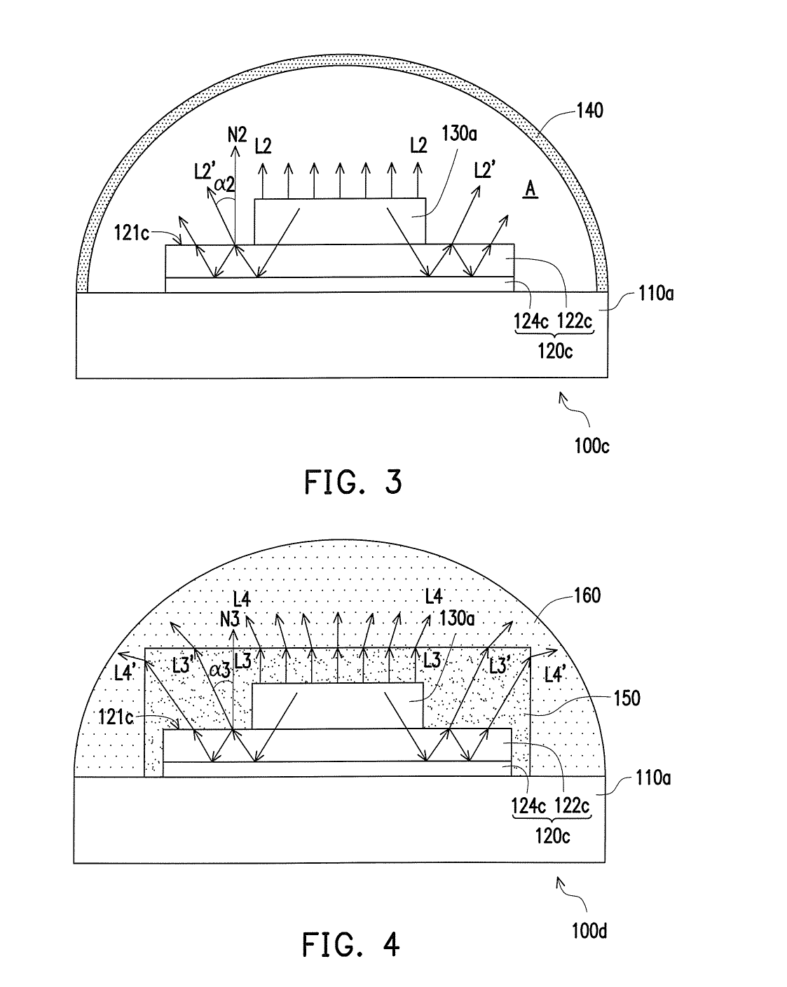

FIG. 3 is a cross-sectional schematic diagram of an LED package structure according to yet another embodiment of the invention. Referring to FIG. 3, the LED package structure 100c of the present embodiment is similar to the LED package structure 100a of FIG. 1. Nevertheless, the main difference between them is that the light guiding component 120c of the present embodiment is composed of a light guiding unit 122c and a reflecting layer 124c. The reflecting layer 124c is disposed between the transparent unit 122c and the package carrier 110a, and the transparent unit 122c has an upper surface 121c. Here, the transparent unit 122c is, for example, a transparent plate or a transparent encapsulant, preferably, the transparent unit 122c is a sapphire substrate, and the reflecting layer 124c is, for example, a Bragg reflector or a metal material layer. As illustrated in FIG. 3, as the light emitting unit 130a emits a light beam L2, a portion of the light beam L2′ will enter the transparent unit 122c of the light guiding component 120c, and the light beam L2′ will be reflected by the reflecting layer 124c, then emit out from the upper surface 121c of the transparent unit 122c. An included angle α2 exists between the light beam L2′ and a normal direction N2 of the upper surface 121c, which ranges from 0 degree to 75 degrees.

Furthermore, the LED package structure 100c of the present embodiment may selectively further include a transparent cover 140, wherein the transparent cover 140 is disposed on the package carrier 100a and covers the light guiding component 120c and the light emitting unit 130a. Here, the material of the transparent cover 140 is, for example, a transparent encapsulant, a glass, or a transparent encapsulant doped with the florescent material. It should be noted that, as the material of the transparent cover 140 is the transparent encapsulant or glass, the emitting light of the overall LED package structure 100c is a mono-color light. Particularly, an air gap A exists between the transparent cover 140c and the package carrier 110a of the present embodiment, but the invention is not limited herein.

FIG. 4 is a cross-sectional schematic diagram of an LED package structure according to yet another embodiment of the invention. Referring to FIG. 4, a LED package structure 100d of the present embodiment is similar to the LED package structure 100c of FIG. 3. But, the main difference between them is that the LED package structure 100d further includes a wavelength-conversion layer 150 and a package encapsulant 160. Specifically, the wavelength-conversion layer 150 is disposed on the package carrier 160 and covers the light emitting unit 130a and the light guiding component 120c. The package encapsulant 160 is disposed on the package carrier 110a and covers the wavelength-conversion layer 150 and the package carrier 110, wherein the horizontal projection area of the light guiding component 120c is smaller than that of the package encapsulant 160. That is, the horizontal projection area of the light guiding component 120c is greater than that of the light emitting unit 130a, but is smaller than the horizontal projection area of the package encapsulant 160. In other words, the package encapsulant 160 will completely cover the light guiding component 120c.

As illustrated in FIG. 4, as the light emitting unit 130a emits a light beam L3, a portion of the light beam L3′ will enter the transparent unit 122c of the light guiding component 120c, and will be reflected by the reflecting layer 124c and emit out from the upper surface 121c of the light emitting unit 122c. Then, the portion of the light beam L3′ emitted out from the upper surface 121c of the transparent unit 122c will stimulate the fluorescent material (not illustrated) in the wavelength-conversion layer 150 to generate a stimulating light L4′, wherein an included angle α3 exists between the light beam L3′and a normal direction N3 of the upper surface 121c, which ranges from 0 degree to 75 degrees. On the other hand, the light beam L3 can also directly generate the stimulating light L4 with the florescent material (not illustrated) in the wavelength-conversion layer 150. That is, the wavelength-conversion layer 150 can covert the light beams L3, L3′ (such as blue light) with the specific wavelength emitted by the light emitting unit 130a into another light beams L4, L4′ (such as yellow light) with the specific wavelength. The light beam (not illustrated) of the light emitting unit 130a, not react with the florescent material, will mix with the simulating light L4, L4′ in the package encapsulant 160 to generate a color mixing light such as a white light.

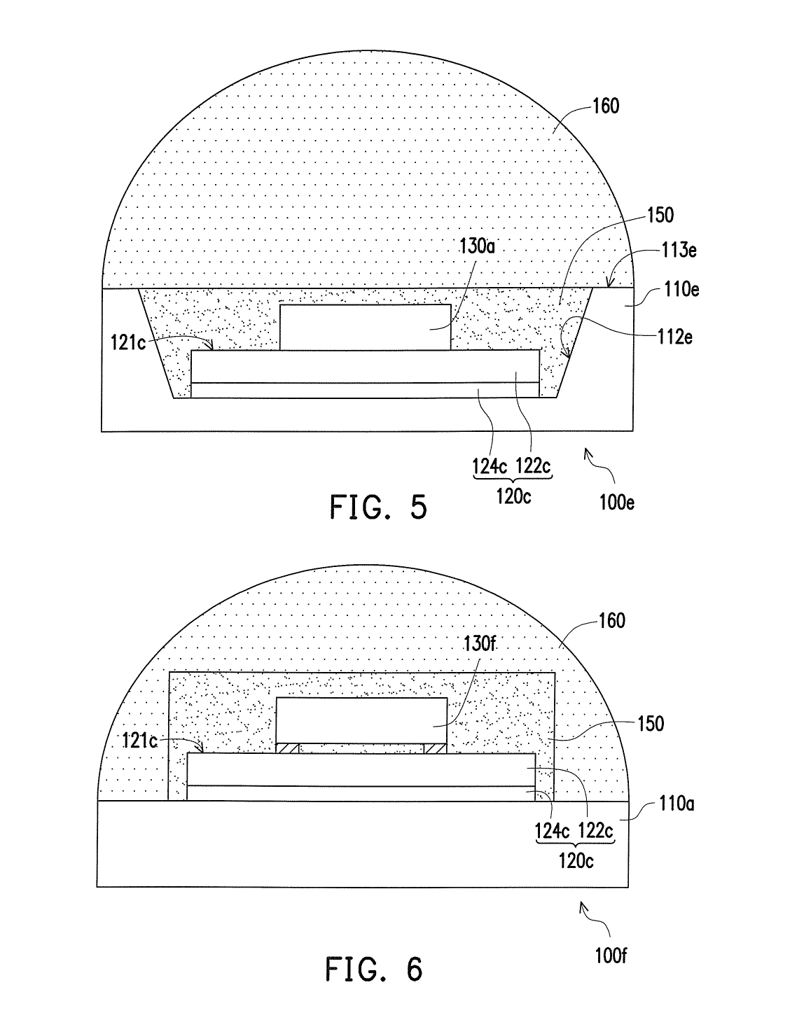

FIG. 5 is a cross-sectional schematic diagram of an LED package structure according to yet another embodiment of the invention. Referring to FIG. 5, a LED package structure 100e of the present embodiment is similar to the LED package structure 100d of FIG. 4. But, the main difference between them is that the package carrier 100e of the present embodiment has a recess 112e, and the light emitting unit 130a and the light guiding unit 120c are located in the recess 112e. As illustrated in FIG. 5, the recess 112e is fully filled with the wavelength-conversion layer 150 and the wavelength-conversion layer 150 completely covers the light emitting unit 130a and the light guiding component 120c, wherein the wavelength-conversion layer 150 is substantially aligned with the surface 113e of the recess 112e, but the invention is not limited herein. Otherwise, the package encapsulant 160 directly covers the surface 113e of the recess 112e and the wavelength-conversion layer 150.

FIG. 6 is a cross-sectional schematic diagram of an LED package structure according to another embodiment of the invention. Referring to FIG. 6, a LED package structure 100f of the present embodiment is similar to the LED package structure 100d of FIG. 4, however, the main difference between them is that a light emitting unit 130f of the present embodiment is embodied as a flip-chip LED.

In addition, in another embodiment not illustrated herein, in order to further increase light emitting angle and brightness, the light guiding component 120b (referring to FIG. 2) with the rough surface as mentioned in the previous embodiment may be adopted. Those skilled in the art may refer to the description of the aforementioned embodiments and select the adequate components according to the practical needs, so as to achieve the required technical effects.

In summary, the LED package structure of the invention has a light guiding component, wherein the horizontal area of the light guiding component is greater than that of the light emitting unit. Therefore, a portion of the light beam emitted by the light emitting unit can expand the light emitting angle of the light emitting unit through the light guiding effect of the light guiding component. As a result, the LED package structure of the present invention can have a broader light emitting angle and the brightness thereof can be enhanced.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. A light-emitting diode package structure, comprising:
a package carrier;
a plate-like light guiding component, disposed on the package carrier;
a light emitting unit, being capable of emitting a light, disposed on a first portion of an upper surface of the light guiding component and at least exposing a second portion of the upper surface of the light guiding component; and
a sealant, sealing the light guiding component and the light emitting unit, wherein the sealant extracts a first portion of the light directly from the light emitting unit and a second portion of the light from the second portion of the upper surface of the light guiding component.

2. The light-emitting diode package structure as claimed in claim 1, wherein the light guiding component comprises a transparent unit and an underlying reflecting layer, wherein the second portion of the light passing through the transparent unit is reflected by the underlying reflecting layer.

3. The light-emitting diode package structure as claimed in claim 1, wherein the second portion of the light passing through the light guiding component is reflected by the package carrier.

4. The light-emitting diode package structure as claimed in claim 1, wherein the light guiding component has no obliquely running side areas.

5. The light-emitting diode package structure as claimed in claim 1, further comprising a fluorescent material distributed in the sealant.

6. The light-emitting diode package structure as claimed in claim 1, wherein the light emitting unit comprises a light emitting layer disposed on a substrate, wherein the substrate directly contacts the light guiding component.

7. The light-emitting diode package structure as claimed in claim 1, wherein the light emitting unit comprises a light emitting layer disposed on a substrate, wherein the light emitting layer is located between the light guiding component and the substrate.

8. The light-emitting diode package structure as claimed in claim 6, wherein the refractive index of the light guiding component is smaller than or equal to the refractive index of the substrate of the light emitting unit.

9. The light-emitting diode package structure as claimed in claim 1, wherein the second portion of the upper surface of the light guiding component comprises a rough surface.

10. The light-emitting diode package structure as claimed in claim 1, wherein the second portion of the upper surface of the light guiding component comprises a rough surface with periodic patterns.

11. A light-emitting diode package structure, comprising:
a package carrier;
a plate-like light guiding component having no obliquely running side areas, disposed on the package carrier;
a light emitting unit, being capable of emitting a light, disposed on a first portion of an upper surface of the light guiding component and at least exposing a second portion of the upper surface of the light guiding component;
a wavelength-conversion layer, covering the light guide component and the light emitting unit, wherein the wavelength-conversion layer extracts a first portion of the light directly from the light emitting unit and a second portion of the light from the second portion of the upper surface of the light guiding component; and
a package encapsulant, encapsulating the package carrier and the wavelength-conversion layer.

12. The light-emitting diode package structure as claimed in claim 11, wherein the package carrier has a recess, and the light guiding component, the light emitting unit and the wavelength-conversion layer are disposed therein.

13. The light-emitting diode package structure as claimed in claim 11, wherein the light guiding component comprises a transparent unit and an underlying reflecting layer, wherein the second portion of the light passing through the transparent unit is reflected by the underlying reflecting layer.

14. The light-emitting diode package structure as claimed in claim 11, wherein the second portion of the light passing through the light guiding component is reflected by the package carrier.

15. The light-emitting diode package structure as claimed in claim 11, wherein the light emitting unit comprises a light emitting layer disposed on a substrate, wherein the substrate directly contacts the light guiding component.

16. The light-emitting diode package structure as claimed in claim 11, wherein the light emitting unit comprises a light emitting layer disposed on a substrate, wherein the light emitting layer is located between the light guiding component and the substrate.

17. The light-emitting diode package structure as claimed in claim 15, wherein the refractive index of the light guiding component is smaller than or equal to the refractive index of the substrate of the light emitting unit.

18. The light-emitting diode package structure as claimed in claim 11, wherein the second portion of the upper surface of the light guiding component comprises a rough surface.

19. A light-emitting diode package structure, comprising:
a package carrier;
a plate-like light guiding unit having no obliquely running side areas, disposed on the package carrier;
a reflecting layer, disposed between the light guiding unit and the package carrier; and
a light emitting unit, being capable of emitting a light, disposed on a first portion of an upper surface of the light guiding unit and at least exposing a second portion of the upper surface of the light guiding unit; and
a wavelength-conversion layer, covering the light guide unit, the reflecting layer and the light emitting unit, wherein the wavelength-conversion layer extracts a first portion of the light directly from the light emitting unit and a second portion of the light from the second portion of the upper surface of the light guiding unit.

20. The light-emitting diode package structure as claimed in claim 19, further comprising a package encapsulant encapsulating the package carrier and the wavelength-conversion layer.
